(19) United States
(12) Patent Application Publication
(10) Pub. No.: US 2025/0311237 A1
(43) Pub. Date: Oct. 2, 2025

(54) VARIABLE RESISTANCE MEMORY DEVICE

(71) Applicant: Samsung Electronics Co., Ltd., Suwon-si (KR)

(72) Inventors: Yongjae KIM, Suwon-si (KR); Kilho LEE, Suwon-si (KR)

(73) Assignee: Samsung Electronics Co., Ltd., Suwon-si (KR)

(21) Appl. No.: 19/087,683

(22) Filed: Mar. 24, 2025

(30) Foreign Application Priority Data
Mar. 29, 2024 (KR) 10-2024-0043672

(51) Int. Cl. H10B 61/00

(52) U.S. Cl. CPC H10B 61/10

(57) ABSTRACT

A variable resistance memory device may include a magnetic tunnel junction structure connected to a cell plug and penetrating a lower dielectric layer covering the cell plug, a capping pattern exposing an upper surface of the magnetic tunnel junction structure and covering both sidewalls of the magnetic tunnel junction structure, an interlayer dielectric layer covering the lower dielectric layer and the capping pattern, an etch stop layer exposing the upper surfaces of the magnetic tunnel junction structure and the capping pattern, an upper dielectric layer covering the etch stop layer, and a contact structure penetrating the upper dielectric layer and the etch stop layer. The contact structure may contact the magnetic tunnel junction structure. The etch stop layer may cover the interlayer dielectric layer and may have a single-layer structure including metal nitride.

### CROSS-REFERENCE TO RELATED APPLICATION

This application is based on and claims priority under 35 U.S.C. § 119 to Korean Patent Application No. 10-2024-0043672, filed on Mar. 29, 2024, in the Korean Intellectual Property Office, the disclosure of which is incorporated by reference herein in its entirety.

### BACKGROUND

Inventive concepts relate to a variable resistance memory device, and more particularly, to a variable resistance memory device including a magnetic tunnel junction structure.

Recently, as the increase in speed and lower power consumption of electronic products, rapid read/write operations and low operating voltages of semiconductor devices embedded in electronic products are required. In response to these demands, highly integrated variable resistance memory devices are emerging as next-generation memory devices because they enable high-speed read and high-speed write operations and are non-volatile. In particular, much research is being conducted on variable resistance memory devices that utilize the magnetoresistance characteristics of a magnetic tunnel junction (MTJ).

### SUMMARY

Inventive concepts provide a variable resistance memory device that exhibits stable performance and improved reliability by forming an etch-stop layer having a high etch selectivity on an upper surface of a magnetic tunnel junction structure and limiting and/or minimizing defects due to etch distribution.

Aspects of inventive concepts are not limited to those mentioned above, and other aspects not mentioned will be clearly understood by those skilled in the art from the following description.

According to an embodiment of inventive concepts, a variable resistance memory device may include a cell plug; a lower dielectric layer covering the cell plug; a magnetic tunnel junction structure connected to the cell plug and penetrating the lower dielectric layer; a capping pattern exposing an upper surface of the magnetic tunnel junction structure and covering both sidewalls of the magnetic tunnel junction structure; an interlayer dielectric layer covering the lower dielectric layer and the capping pattern; an etch stop layer exposing the upper surface of the magnetic tunnel junction structure and an upper surface of the capping pattern, the etch stop layer covering the interlayer dielectric layer; an upper dielectric layer covering the etch stop layer; and a contact structure penetrating the upper dielectric layer and the etch stop layer, the contact structure contacting the magnetic tunnel junction structure. The etch stop layer may have a stack structure including a lower etch stop layer and an upper etch stop layer on the lower etch stop layer. The lower etch stop layer may include metal nitride, and the upper etch stop layer may include oxygen doped carbide.

According to an embodiment of inventive concepts, a variable resistance memory device may include a cell plug; a lower dielectric layer covering the cell plug; a magnetic tunnel junction structure connected to the cell plug and penetrating the lower dielectric layer; a capping pattern exposing an upper surface of the magnetic tunnel junction structure and covering both sidewalls of the magnetic tunnel junction structure; an interlayer dielectric layer covering the lower dielectric layer and the capping pattern; an etch stop layer exposing the upper surface of the magnetic tunnel junction structure and an upper surface of the capping pattern, the etch stop layer covering the interlayer dielectric layer and having a single-layer structure including metal nitride; an upper dielectric layer covering the etch stop layer; and a contact structure penetrating the upper dielectric layer and the etch stop layer, the contact structure contacting the magnetic tunnel junction structure.

According to an embodiment of inventive concepts, a variable resistance memory device may include a substrate including a cell area and a peripheral circuit area surrounding the cell area; a cell plug on the cell area; a lower dielectric layer covering the cell plug; a magnetic tunnel junction structure connected to the cell plug and penetrating the lower dielectric layer, the magnetic tunnel junction structure including a lower electrode, a magnetic tunnel junction pattern, and an upper electrode; a capping pattern covering both sidewalls of the magnetic tunnel junction structure; an interlayer dielectric layer covering the lower dielectric layer and the capping pattern; an etch stop layer covering the interlayer dielectric layer and including at least one layer including metal nitride; an upper dielectric layer covering the etch stop layer; and a contact structure penetrating the upper dielectric layer and the etch stop layer, the contact structure contacting the magnetic tunnel junction structure.

### BRIEF DESCRIPTION OF THE DRAWINGS

Embodiments will be more clearly understood from the following detailed description taken in conjunction with the accompanying drawings in which:

FIG. 1 is a circuit diagram showing a cell array of a variable resistance memory device according to an embodiment;

FIG. 2 is a circuit diagram showing a magnetoresistive memory cell of FIG. 1;

FIG. 3 is a perspective view showing the magnetoresistive memory cell of FIG. 2;

FIG. 4 is a plan view for explaining a variable resistance memory device according to an embodiment;

FIG. 5 is a cross-sectional view showing a variable resistance memory device according to an embodiment;

FIG. 6 is an enlarged view of a portion CX1 of FIG. 5;

FIG. 7 is a cross-sectional view showing a variable resistance memory device according to another embodiment;

FIG. 8 is an enlarged view of a portion CX2 of FIG. 7;

FIG. 9 is a flowchart showing a method of manufacturing a variable resistance memory device according to an embodiment;

FIGS. 10 to 20 are cross-sectional views showing a method of manufacturing a variable resistance memory device in process sequence, according to an embodiment;

FIG. 21 is a configuration diagram of a data processing system including a variable resistance memory device according to an embodiment; and

FIG. 22 is a configuration diagram of a data processing system including a variable resistance memory device according to an embodiment.

### DETAILED DESCRIPTION OF THE EMBODIMENTS

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C,” “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

The notion that elements are “substantially the same” may indicate that the element may be completely the same and may also indicate that the elements may be determined to be the same in consideration of errors or deviations occurring during a process.

Hereinafter, embodiments of inventive concepts will be described in detail with reference to the attached drawings.

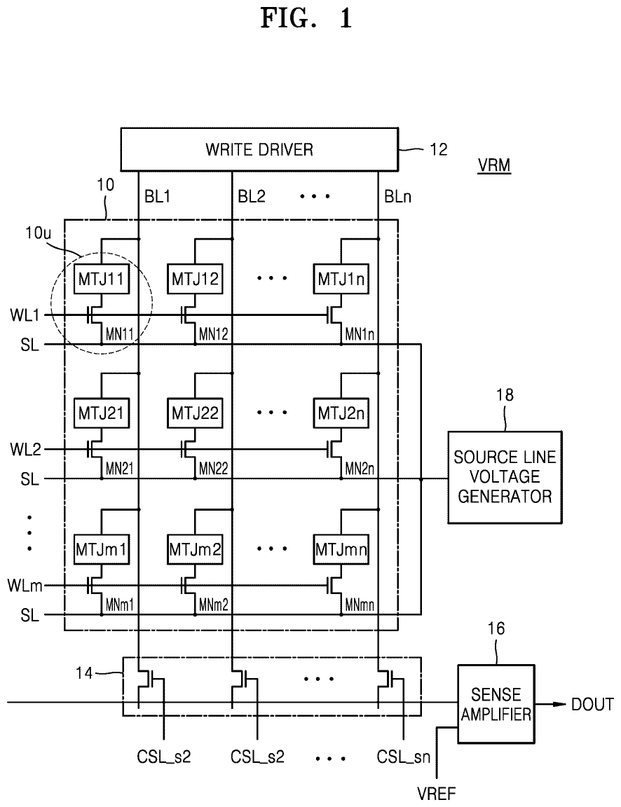

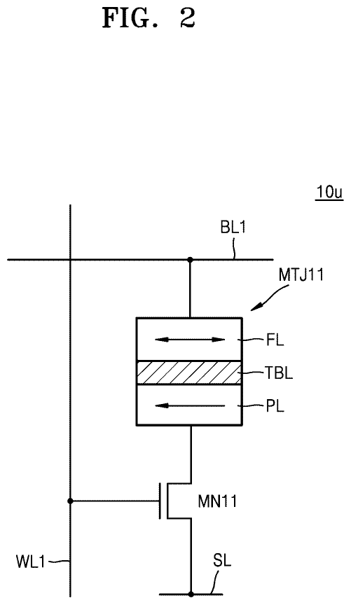

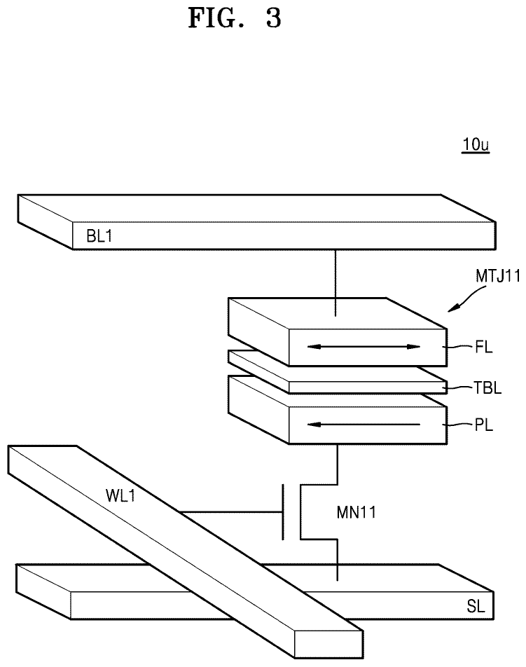

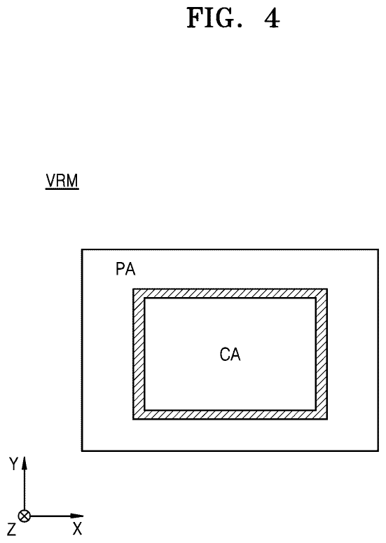

FIG. 1 is a circuit diagram showing a cell array of a variable resistance memory device according to an embodiment. FIG. 2 is a circuit diagram showing a magnetoresistive memory cell of FIG. 1. FIG. 3 is a perspective view showing the magnetoresistive memory cell of FIG. 2. FIG. 4 is a plan view to explain a variable resistance memory device according to an embodiment.

Referring to FIGS. 1 to 4 together, a variable resistance memory device VRM may be a magnetoresistive memory device in one embodiment.

As shown in FIG. 1, the magnetoresistive memory device VRM may include magnetoresistive RAM (MRAM). The variable resistance memory device VRM may include a magnetic tunnel junction (MTJ), which includes a variable resistance layer.

The variable resistance memory device VRM may include a magnetoresistive memory cell array 10. The magnetoresistive memory cell array 10 may also be referred to as a cell array. The magnetoresistive memory cell array 10 may be connected to a write driver 12, a selection circuit 14, a source line voltage generator 18, and a sense amplifier 16.

The magnetoresistive memory cell array 10 may include a plurality of magnetoresistive memory cells 10u. The magnetoresistive memory cell 10u may also be referred to as a memory cell. The magnetoresistive memory cell array 10 may include a plurality of word lines WL1 to WLm and a plurality of bit lines BL1 to BLn. The magnetoresistive memory cell array 10 may have a magnetoresistive memory cell 10u between each of the plurality of word lines WL1 to WLm and each of the plurality of bit lines BL1 to BLn.

The magnetoresistive memory cell array 10 may include a plurality of cell transistors MN11 to MNmn having gates connected to the plurality of word lines WL1 to WLm, and a plurality of magnetic tunnel junctions MTJ11 to MTJmn connected between each of the plurality of cell transistors MN11 to MNmn and each of the plurality of bit lines BL1 to BLn and forming a variable resistance layer.

The write driver 12 is connected to the plurality of bit lines BL1 to BLn, generates a program current based on write data, and provides the program current to the plurality of bit lines BL1 to BLn.

The selection circuit 14 may selectively connect a plurality of bit lines BL1 to BLn to the sense amplifier 16 in response to a plurality of column selection signals CSL_s1 to CSL_sn. The sense amplifier 16 may generate output data DOUT by amplifying the difference between the output voltage signal of the selection circuit 14 and a reference voltage VREF.

Sources of each of the plurality of cell transistors MN11 to MNmn may be connected to a source line SL. In order to magnetize the plurality of magnetic tunnel junctions MTJ11 to MTJmn in the magnetoresistive memory cell array 10, a voltage higher than a voltage applied to the plurality of bit lines BL1 to BLn may be applied to the source line SL. The source line voltage generator 18 may generate a source line driving voltage VSL and provide the source line driving voltage VSL to the source line SL of the magnetoresistive memory cell array 10.

As shown in FIG. 2, the magnetoresistive memory cell 10u may include, for example, a cell transistor MN11 including an NMOS transistor and a magnetic tunnel junction MTJ11. The cell transistor MN11 includes a gate connected to the word line WL1 and a source connected to the source line SL. The magnetic tunnel junction MTJ11 is connected between a drain of the cell transistor MN11 and the bit line BL1.

As shown in FIG. 3, the magnetic tunnel junction MTJ11 may include a pinned layer PL having a fixed magnetization direction, a free layer FL magnetized in a direction of a magnetic field applied from the outside, and a tunnel barrier layer TBL formed as an dielectric layer between the pinned layer PL and the free layer FL.

In some embodiments, the pinned layer PL may include any one selected from iron manganese (FeMn), iridium manganese (IrMn), platinum manganese (PtMn), manganese oxide (MnO), manganese sulfide (MnS), manganese tellurium (MnTe), manganese fluoride (MnF₂), iron fluoride (FeF₂), iron chloride (FeCl₂), iron oxide (FeO), cobalt chloride (CoCl₂), cobalt oxide (CoO), nickel chloride (NiCl₂), nickel oxide (NiO), chromium (Cr), iron (Fe), nickel (Ni), cobalt (Co), ruthenium (Ru), iridium (Ir), and rhodium (Rh).

In some embodiments, the free layer FL may be a ferromagnetic material including at least one of Fe, Ni, and Co.

In some embodiments, the tunnel barrier layer TBL may include aluminum oxide (AIO) or magnesium oxide (MgO).

The magnetic tunnel junction MTJ11 may be included in a memory cell that constitutes a spin transfer torque (STT)-MRAM.

For a write operation of STT-MRAM, a logic high voltage is applied to the word line WL1 to turn on the cell transistor MN11, and a write current may be applied between the bit line BL1 and the source line SL.

For a read operation of STT-MRAM, a logic high voltage is applied to the word line WL1 to turn on the cell transistor MN11, and a read current is applied in a direction from the bit line BL1 to the source line SL to determine data stored in the magnetoresistive memory cell 10u according to a resistance value of the magnetic tunnel junction MTJ11 with respect to the read current.

The resistance value of the magnetic tunnel junction MTJ11 varies according to the magnetization direction of the free layer FL. For example, in the magnetic tunnel junction MTJ11, the magnetization direction of the free layer FL and the magnetization direction of the pinned layer PL may be arranged in parallel. In this case, the magnetic tunnel junction MTJ11 may have a low resistance value and may read data (e.g., 0). Also, in the magnetic tunnel junction MTJ11, the magnetization direction of the free layer FL may be antiparallel to the magnetization direction of the pinned layer PL. In this case, the magnetic tunnel junction MTJ11 may have a high resistance value and may read data (e.g., 1).

In the drawing, the magnetization direction of the free layer FL and the pinned layer PL of the magnetic tunnel junction MTJ11 is shown as a horizontal magnetic device, but in some other embodiments, a vertical magnetic device in which the magnetization directions of the free layer FL and the pinned layer PL are vertical may also be used.

As shown in FIG. 4, the variable resistance memory device VRM may include a cell area CA and a peripheral circuit area PA surrounding the cell area CA. In some embodiments, the variable resistance memory device VRM may include a boundary area between the cell area CA and the peripheral circuit area PA.

The cell area CA may include an area where the magnetoresistive memory cell array 10 of FIG. 1 is disposed. Also, the cell area CA may be an area where the magnetoresistive memory cell 10u described with reference to FIGS. 1 and 2 is disposed.

In the peripheral circuit area PA, peripheral circuits and peripheral transistors that control the magnetoresistive memory cell array 10 of the cell area CA may be disposed. That is, the peripheral circuit area PA may be an area where the core/ferry circuit is disposed.

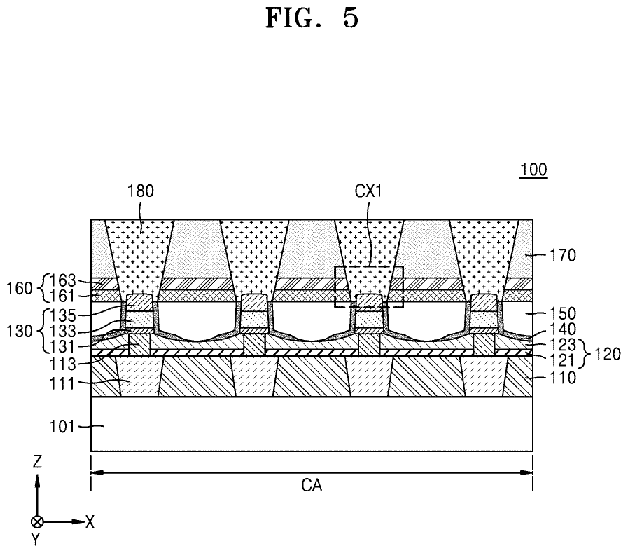

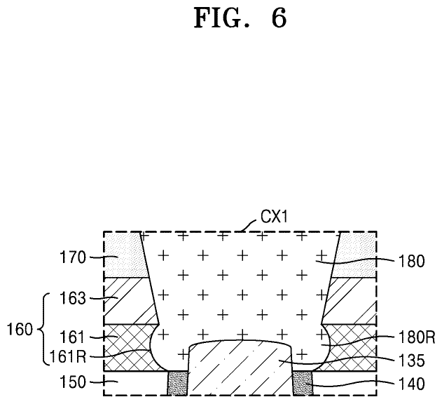

FIG. 5 is a cross-sectional view showing a variable resistance memory device 100 according to an embodiment. FIG. 6 is an enlarged view of a portion CX1 of FIG. 5.

Referring to FIGS. 5 and 6 together, the variable resistance memory device 100 is shown including an etch stop layer 160 having a high etch selectivity on an upper surface of a magnetic tunnel junction structure 130.

In the variable resistance memory device 100, a substrate 101 may be a semiconductor wafer including silicon (Si), germanium (Ge), silicon carbide (SiC), gallium arsenide (GaAs), indium arsenide (InAs), or indium phosphide (InP). In some embodiments, the substrate 101 may include an impurity-doped well or an impurity-doped structure, which is a conductive region.

Although not shown, a cell transistor may be formed on the substrate 101 in the cell area CA. The cell transistor may be configured as a buried gate type transistor. Also, a peripheral circuit transistor may be formed on the substrate 101 in the peripheral circuit area PA (see FIG. 4). The peripheral circuit transistor may be configured as a planar-type transistor.

A base dielectric layer 110 may be disposed on the substrate 101, and a plurality of cell plugs 111 penetrating the base dielectric layer 110 may be disposed. Specifically, the plurality of cell plugs 111 may be arranged to be connected to a cell transistor or to a lower metal line (not shown) in the cell area CA.

A lower dielectric layer 120 covering the plurality of cell plugs 111 may be disposed on the substrate 101. The lower dielectric layer 120 may include a first lower dielectric layer 121 and a second lower dielectric layer 123 formed on the first lower dielectric layer 121. The first lower dielectric layer 121 and the second lower dielectric layer 123 may include materials different from each other. In some embodiments, the first lower dielectric layer 121 may include a SiCN film, a SiOC film, a SiOF film, a SiCH film, a SiOCH film, or any combination thereof. The second lower dielectric layer 123 may include a tetracthoxysilane (TEOS) film but is not limited thereto.

A plurality of pad electrodes 113 that contact the plurality of cell plugs 111 and are electrically connected thereto may be disposed penetrating through the lower dielectric layer 120.

A plurality of magnetic tunnel junction structures 130 may be placed in contact with the plurality of pad electrodes 113 and electrically connected thereto. In some embodiments, the plurality of magnetic tunnel junction structures 130 may be disposed on crossing points in a mesh structure in a first horizontal direction (X direction) and a second horizontal direction (Y direction). Additionally, the plurality of magnetic tunnel junction structures 130 may form memory cells.

A plurality of magnetic tunnel junction structures 130 may be formed on a plurality of cell plugs 111 in the cell area CA. That is, the plurality of magnetic tunnel junction structures 130 may be electrically connected to the plurality of cell plugs 111 through the plurality of pad electrodes 113.

Each of the plurality of magnetic tunnel junction structures 130 may have a structure in which a lower electrode 131, a magnetic tunnel junction pattern 133, and an upper electrode 135 are stacked. The magnetic tunnel junction pattern 133 constitutes a variable resistance layer and, as previously described with reference to FIGS. 2 and 3, may include a pinned layer PL, a tunnel barrier layer TBL, and a free layer FL. The lower electrode 131 and the upper electrode 135 may include a conductive material such as metal.

In some embodiments, in the process of forming the plurality of magnetic tunnel junction structures 130, a portion of an upper surface of the second lower dielectric layer 123 may be etched together, and thus, the second lower dielectric layer 123 may have a rounded upper surface.

A capping pattern 140 may be disposed on both sidewalls of each of the plurality of magnetic tunnel junction structures 130. The capping pattern 140 may include a dielectric material. For example, the capping pattern 140 may include silicon nitride (SiN).

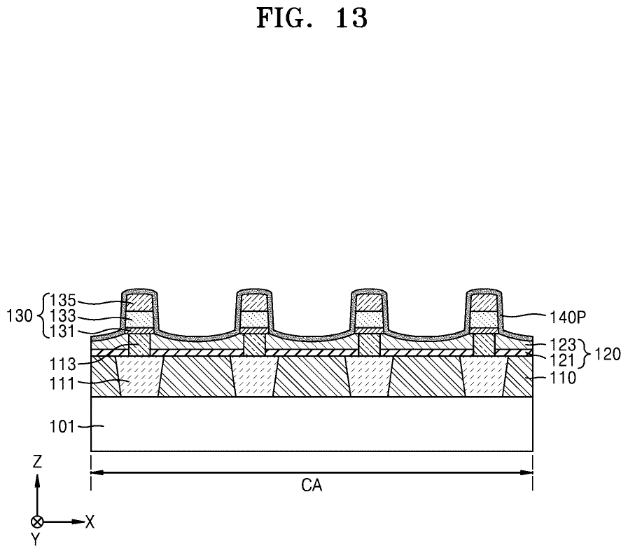

As described below, the capping pattern 140 may be formed by performing an entire surface etching process on the capping layer 140P (see FIG. 13). If the entire surface etching process is anisotropic etching, the capping pattern 140 may be formed on both sidewalls of the magnetic tunnel junction structure 130. Also, between adjacent magnetic tunnel junction structures 130, the capping pattern 140 may be disposed to be discontinuously formed. At portions where the capping pattern 140 is discontinued, the lower dielectric layer 120 and an interlayer dielectric layer 150, which described below, may contact each other.

Through the entire surface etching process, the upper surface of the plurality of magnetic tunnel junction structures 130 and the rounded upper surface of the second lower dielectric layer 123 may be exposed to the outside in the cell area CA. Specifically, the capping pattern 140 may expose a portion of sidewalls and an upper surface of the upper electrode 135 of the magnetic tunnel junction structure 130 and may cover sidewalls of the lower electrode 131 and sidewalls of the magnetic tunnel junction pattern 133. Accordingly, a vertical level of the upper surface of the magnetic tunnel junction structure 130 may be higher than a vertical level of an upper surface of the capping pattern 140.

The interlayer dielectric layer 150 may fill a space between the plurality of magnetic tunnel junction structures 130 without voids. In some embodiments, the interlayer dielectric layer 150 may include a material having a low dielectric constant that is lower than that of silicon oxide. The interlayer dielectric layer 150 may include a material having a low dielectric constant of less than 3.9, for example, a low-k (LK) dielectric, an ultra-low k (ULK) dielectric, an extreme low-k (ELK) dielectric, etc.

In the variable resistance memory device 100 according to inventive concepts, the etch stop layer 160 may be disposed to expose the upper surface of the magnetic tunnel junction structure 130 and the uppermost surface of the capping pattern 140 and cover the interlayer dielectric layer 150.

In some embodiments, the etch stop layer 160 may have a stack structure. For example, the etch stop layer 160 may include a lower etch stop layer 161 including metal nitride and an upper etch stop layer 163 including oxygen doped carbide. For example, the lower etch stop layer 161 may include aluminum nitride (AlN), and the upper etch stop layer 163 may include silicon oxycarbide (SiOC) or silicon carbide (SiC), but are not limited thereto.

That is, the material constituting the lower etch stop layer 161 may have a high etch selectivity with respect to the material constituting the upper etch stop layer 163 and a material constituting an upper dielectric layer 170. Additionally, the upper etch stop layer 163 may protect the lower etch stop layer 161.

In some embodiments, a vertical level of a lower surface of the lower etch stop layer 161 may be substantially the same as the vertical level of the uppermost surface of the capping pattern 140, and a vertical level of a lower surface of the upper etch stop layer 163 may be higher than a vertical level of the upper surface of the magnetic tunnel junction structure 130.

In some embodiments, the lower etch stop layer 161 may have a concavely rounded sidewall 161R, and the upper etch stop layer 163 may have a tapered sidewall. These characteristics may be due to differences in the etching process, which is described below.

The upper dielectric layer 170 may be disposed to cover the etch stop layer 160. In some embodiments, the upper dielectric layer 170 may include a tetraethoxysilane (TEOS) film. In other embodiments, the upper dielectric layer 170 may include a SiON film, a SiOC film, a SiOF film, a SiCH film, a SiOCH film, or any combination thereof.

A contact structure 180 in contact with the magnetic tunnel junction structure 130 may be disposed in the cell area CA. Specifically, the contact structure 180 may be disposed to contact a portion of the sidewall and the upper surface of the upper electrode 135 of the magnetic tunnel junction structure 130 exposed from the capping pattern 140.

In the variable resistance memory device 100 according to inventive concepts, among sidewalls of the contact structure 180, a lower sidewall 180R in contact with the lower etch stop layer 161 has a convex round shape, and among the sidewalls of the contact structure 180, an upper sidewall contacting the upper etch stop layer 163 and the upper dielectric layer 170 may have a tapered shape. The shape of the contact structure 180 may result from the shape of the sidewall of the lower etch stop layer 161.

Although not shown, a contact structure in contact with a peripheral plug may be disposed in the peripheral circuit area PA (see FIG. 4).

According to the demand for the highly integrated variable resistance memory device 100 and the development of manufacturing process technology, an area of the semiconductor wafer becomes larger, and a pitch between neighboring magnetoresistive memory cells 10u (see FIG. 1) is further decreasing.

Generally, in a process of forming a contact hole in which the contact structure 180 is disposed, dielectric layers (e.g., a lower dielectric layer, an interlayer dielectric layer, and an upper dielectric layer) constituting the cell area CA include similar dielectric materials, and thus, the dielectric layers may have a low etch selectivity between each other. In addition, the conventional etch stop layer disposed on the magnetic tunnel junction structure 130 may also include a material (e.g., silicon nitride or silicon carbonitride) having a low etch selectivity with respect to the dielectric layers.

Accordingly, in order to form the contact structure 180 that electrically connects the magnetic tunnel junction structure 130 to the bit line BL1 (see FIG. 3) in the variable resistance memory device 100, it may be very difficult to form the contact holes without distribution defects, such as over-etching and/or under-etching.

However, in the variable resistance memory device 100 according to inventive concepts, the etch stop layer 160 having a high etch selectivity with respect to the upper dielectric layer 170 is formed on the upper surface of the magnetic tunnel junction structure 130, and thus, defects of the contact structure 180 due to etch distribution may be limited and/or minimized. Ultimately, the variable resistance memory device 100 according to inventive concepts has the effect of providing stable performance and improved reliability.

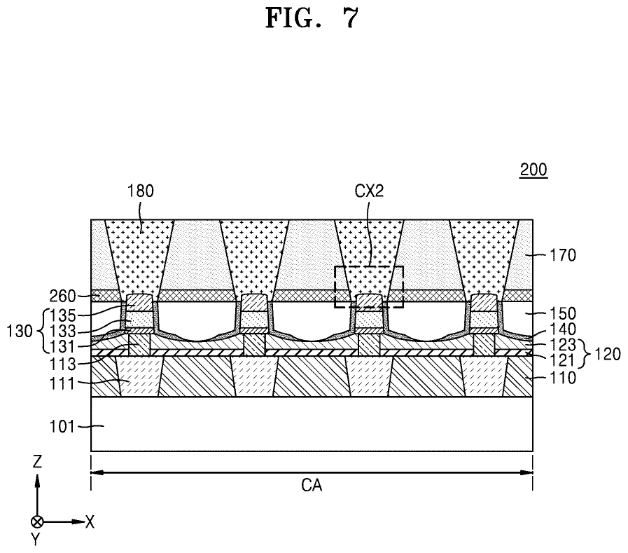

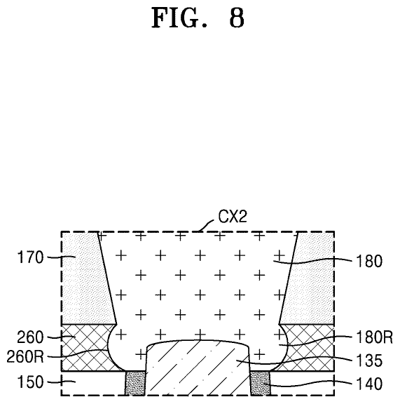

FIG. 7 is a cross-sectional view showing a variable resistance memory device 200 according to another embodiment. FIG. 8 is an enlarged view of portion CX2 of FIG. 7.

Most of the components constituting the variable resistance memory device 200 described below and materials for forming the components are substantially the same or similar to those previously described with respect to FIGS. 5 and 6. Therefore, for convenience of explanation, the description will focus on differences from the variable resistance memory device 100 described above.

Referring to FIGS. 7 and 8 together, the variable resistance memory device 200 including an etch stop layer 260 having a high etch selectivity on the upper surface of the magnetic tunnel junction structure 130 is shown.

The variable resistance memory device 200 according to an embodiment may include a single etch stop layer 260 that exposes the upper surface of the magnetic tunnel junction structure 130 and the upper surface of the capping pattern 140 and covers the interlayer dielectric layer 150.

In some embodiments, the etch stop layer 260 may include metal nitride. Specifically, the etch stop layer 260 may include AlN but is not limited thereto.

That is, the material constituting the etch stop layer 260 may have a high etch selectivity with respect to the material constituting the upper dielectric layer 170.

In some embodiments, a vertical level of a lower surface of the etch stop layer 260 may be substantially the same as a vertical level of the upper surface of the capping pattern 140, and a vertical level of a lower surface of the upper dielectric layer 170 may be higher than the vertical level of the upper surface of the magnetic tunnel junction structure 130.

In some embodiments, the etch stop layer 260 may have a concavely rounded sidewall 260R, and the upper dielectric layer 170 may have a tapered sidewall.

The variable resistance memory device 200 according to inventive concept forms the upper dielectric layer 170 and the etch stop layer 260 having a high etch selectivity on the upper surface of the magnetic tunnel junction structure 130, and thus, may minimize defects in the contact structure 180 due to the etch distribution. Ultimately, the variable resistance memory device 200 according to inventive concepts has the effect of providing stable performance and improved reliability.

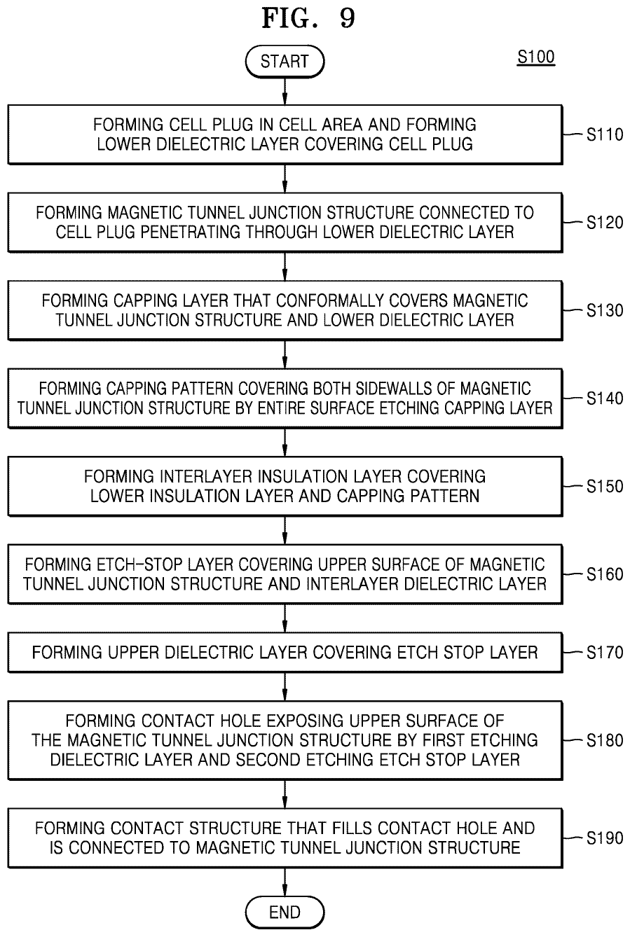

FIG. 9 is a flowchart showing a method of manufacturing a variable resistance memory device according to an embodiment.

Referring to FIG. 9, the method (S100) of manufacturing a variable resistance memory device may include process sequences of first to ninth operations S110 to S190.

If an embodiment may be implemented differently, a specific process sequence may be performed differently from the described sequence. For example, two processes described consecutively may be performed substantially at the same time or may be performed in an order opposite to the order in which they are described.

The method (S100) of manufacturing a variable resistance memory device according to inventive concepts may include forming a cell plug in a cell area and forming a lower dielectric layer covering the cell plug (S110), forming a magnetic tunnel junction structure connected to the cell plug penetrating through the lower dielectric layer (S120), forming a capping layer that conformally covers the magnetic tunnel junction structure and the lower dielectric layer (S130), forming a capping pattern covering both sidewalls of the magnetic tunnel junction structure by entire surface etching the capping layer (S140), forming an interlayer insulation layer covering the lower insulation layer and the capping pattern (S150), forming an etch-stop layer covering an upper surface of the magnetic tunnel junction structure and the interlayer dielectric layer (S160), forming an upper dielectric layer covering the etch stop layer (S170), forming a contact hole exposing the upper surface of the magnetic tunnel junction structure by first etching the dielectric layer and second etching the etch stop layer (S180), and forming a contact structure that fills the contact hole and is connected to the magnetic tunnel junction structure (S190).

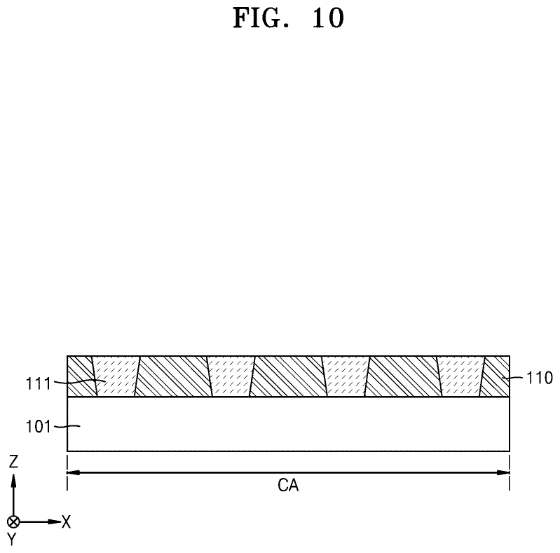

Technical features of each of the first to ninth operations (S110 to S190) are described in detail with reference to FIGS. 10 to 20 below.

FIGS. 10 to 20 are cross-sectional views showing a method of manufacturing a variable resistance memory device in a process sequence, according to an embodiment.

Referring to FIG. 10, a substrate 101 including a cell area CA and a peripheral circuit area PA (scc FIG. 4) may be prepared.

The substrate 101 may be a semiconductor wafer including Si, Ge, SiC, GaAs, InAs, or InP.

Next, a base dielectric layer 110 may be formed on the substrate 101, and a plurality of cell plugs 111 penetrating the base dielectric layer 110 may be formed.

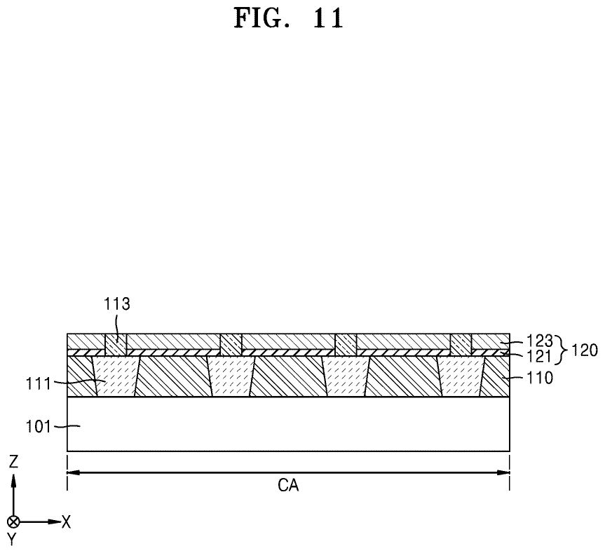

Referring to FIG. 11, a lower dielectric layer 120 may be formed to cover the plurality of cell plugs 111.

The lower dielectric layer 120 may include a first lower dielectric layer 121 and a second lower dielectric layer 123. The first lower dielectric layer 121 and the second lower dielectric layer 123 may include materials different from each other.

Next, a plurality of pad electrodes 113 that contact the plurality of cell plugs 111 by penetrating the lower dielectric layer 120 and are electrically connected thereto may be formed.

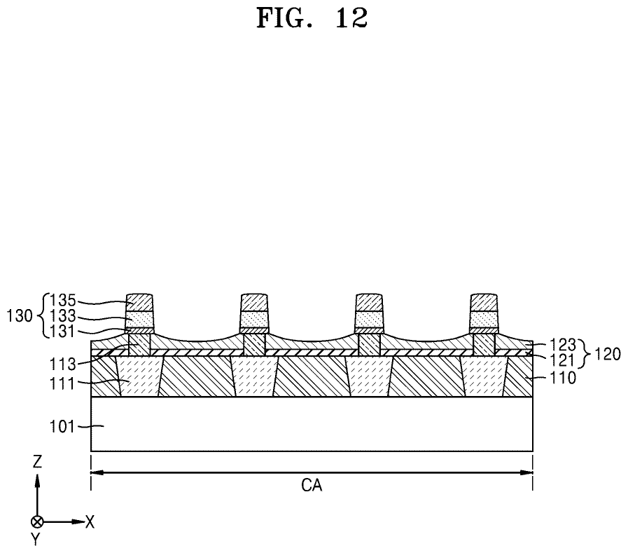

Referring to FIG. 12, a plurality of magnetic tunnel junction structures 130 that are in contact with the plurality of pad electrodes 113 and are electrically connected thereto may be formed.

The plurality of magnetic tunnel junction structures 130 may be disposed on crossing points in a mesh structure in a first horizontal direction (X direction) and a second horizontal direction (Y direction). Additionally, the plurality of magnetic tunnel junction structures 130 may configure memory cells.

In some embodiments, each of the plurality of magnetic tunnel junction structures 130 may have a structure in which a lower electrode 131, a magnetic tunnel junction pattern 133, and an upper electrode 135 are stacked.

In some embodiments, in the process of forming the plurality of magnetic tunnel junction structures 130, a portion of an upper surface of the second lower dielectric layer 123 may be etched together, and thus, the second lower dielectric layer 123 may have a rounded upper surface.

Referring to FIG. 13, a capping layer 140P that conformally covers the upper surfaces of the plurality of magnetic tunnel junction structures 130 and the lower dielectric layer 120 may be formed.

The capping layer 140P may be formed to protect the plurality of magnetic tunnel junction structures 130. The capping layer 140P may include a dielectric material. For example, the capping layer 140P may include SiN.

The capping layer 140P covers both the upper and side surfaces of the plurality of magnetic tunnel junction structures 130 and may extend between adjacent magnetic tunnel junction structures 130. Accordingly, the capping layer 140P may be referred to as an encapsulation layer.

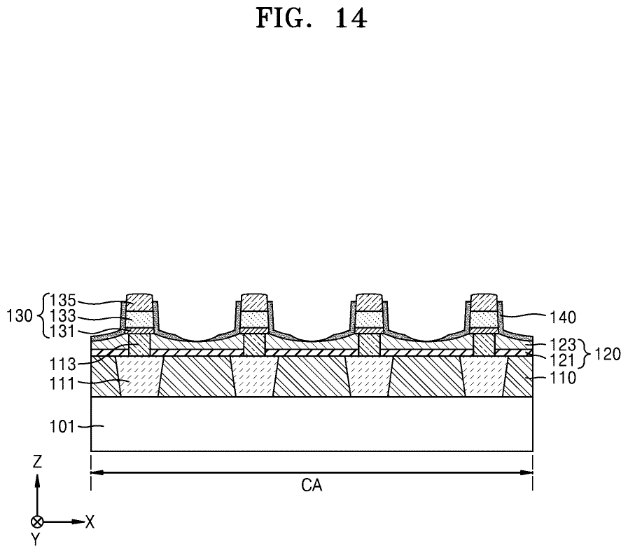

Referring to FIG. 14, a capping pattern 140 may be formed on both sidewalls of the magnetic tunnel junction structure 130 by performing an entire surface etching process.

A significant portion of the capping layer 140P (see FIG. 13) located at the top in the cell area CA may be etched by the entire surface etching process.

If the entire surface etching process is anisotropic etching (e.g., dry etching), the capping patterns 140 may be formed on both sidewalls of the magnetic tunnel junction structure 130. By the entire surface etching process, a portion of a sidewall and an upper surface of the upper electrode 135 of the magnetic tunnel junction structure 130 and the rounded upper surface of the second lower dielectric layer 123 are exposed to the outside in the cell area CA.

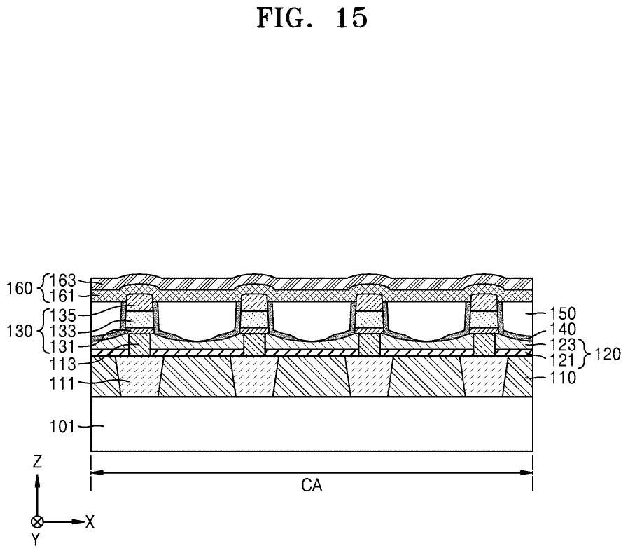

Referring to FIG. 15, an interlayer dielectric layer 150 may be formed between the plurality of magnetic tunnel junction structures 130 without voids.

In some embodiments, the interlayer dielectric layer 150 may include a material having a low dielectric constant that is lower than that of silicon oxide. The interlayer dielectric layer 150 may include a material having a low dielectric constant of less than 3.9, for example, an LK dielectric, a ULK dielectric, an ELK dielectric, etc.

Next, an etch stop layer 160 may be formed to cover the upper surface of the magnetic tunnel junction structure 130, the upper surface of the capping pattern 140, and the interlayer dielectric layer 150.

In some embodiments, the etch stop layer 160 may have a stack structure. For example, the etch stop layer 160 may include a lower etch stop layer 161 including metal nitride and an upper etch stop layer 163 including oxygen doped carbide.

The material constituting the lower etch stop layer 161 may have a high etch selectivity with respect to a material constituting the upper etch stop layer 163 and a material constituting the upper dielectric layer 170.

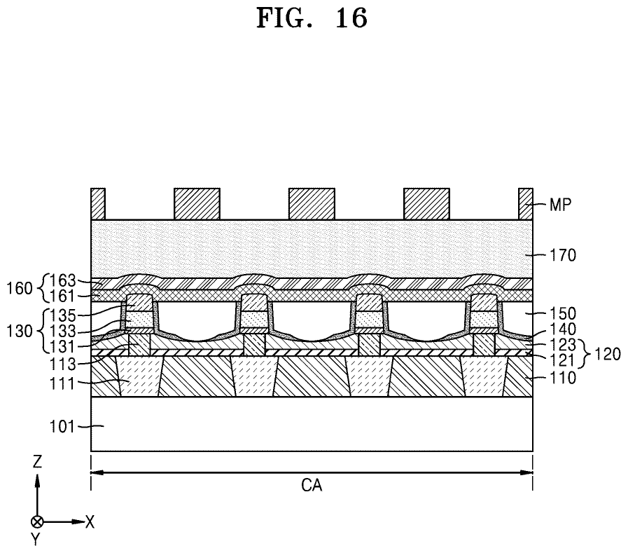

Referring to FIG. 16, the upper dielectric layer 170 may be formed to cover the etch stop layer 160.

The upper dielectric layer 170 may cover the upper etch stop layer 163 and may be formed to have a thickness greater than that of the etch stop layer 160. In some embodiments, the upper dielectric layer 170 may include a TEOS film. In other embodiments, the upper dielectric layer 170 may include a SiON film, a SiOC film, a SiOF film, a SiCH film, a SiOCH film, or any combination thereof.

Next, a mask pattern MP may be formed on the upper dielectric layer 170. The mask pattern MP may be formed using photolithography and developing processes. Because the photolithography and development processes are common techniques to those skilled in the art, detailed descriptions thereof are omitted.

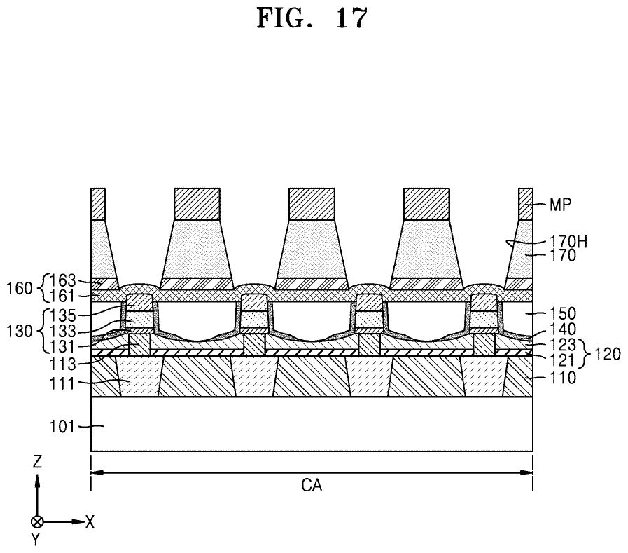

Referring to FIG. 17, the upper dielectric layer 170 and the upper etch stop layer 163 may be dry etched using the mask pattern MP as an etch mask.

Through the dry etching, a plurality of contact holes 170H exposing the upper etch stop layer 163 may be formed. Due to the nature of the anisotropic etching result of dry etching, each of the plurality of contact holes 170H may have an inverted trapezoidal tapered shape.

The plurality of contact holes 170H may be formed to overlap the plurality of magnetic tunnel junction structures 130 in the vertical direction (Z direction).

Next, the mask pattern MP may be removed through an ashing and stripping process.

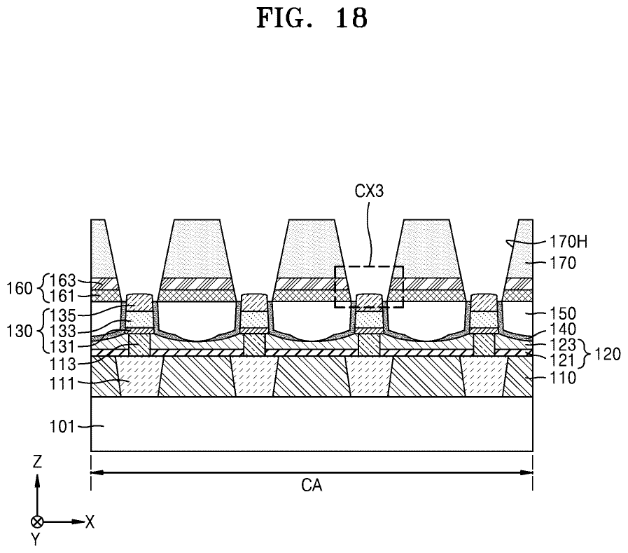

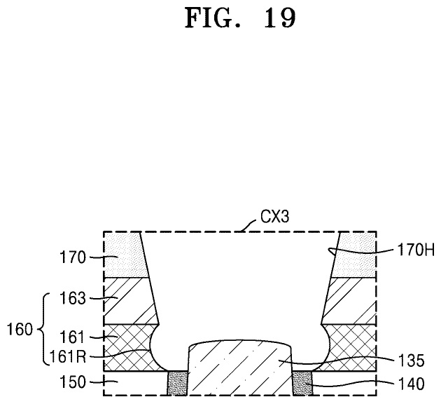

Referring to FIGS. 18 and 19 together, the upper etch stop layer 163 exposed through the plurality of contact holes 170H may be wet etched. Specifically, FIG. 19 is an enlarged view showing a portion CX3 of FIG. 18.

Through the wet etching, a portion of the lower etch stop layer 161 may be removed to expose the upper surface of the magnetic tunnel junction structure 130. Due to the nature of the isotropic etching result of wet etching, the lower etch stop layer 161 may have a concavely rounded sidewall 161R. That is, a dry etching process may be performed on the upper etch stop layer 163, and a wet etching process may be performed on the lower etch stop layer 161.

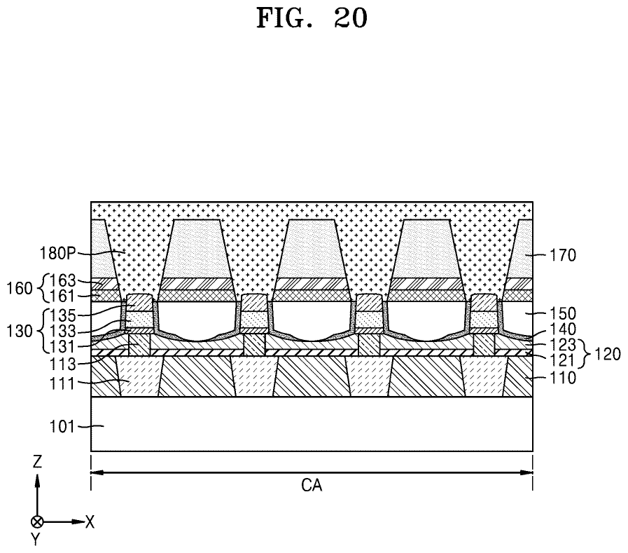

Referring to FIG. 20, a contact metal layer 180P may be formed to fill a plurality of contact holes 170H (see FIG. 18).

The contact metal layer 180P may be formed to contact the plurality of magnetic tunnel junction structures 130.

In some embodiments, the contact metal layer 180P may be formed as a double-layer structure including a metal barrier film (not shown) and a metal buried layer (not shown) covering the metal barrier film. In other embodiments, the contact metal layer 180P may be formed as a single layer structure of the metal buried layer.

Referring again to FIG. 5, after the process of forming the contact metal layer 180P, the contact metal layer 180P is separated into nodes, and a contact structure 180 that is in contact with and electrically connected to the magnetic tunnel junction structure 130 may be formed in the cell area CA.

Through the manufacturing process described above, the variable resistance memory device 100 according to inventive concepts may be manufactured.

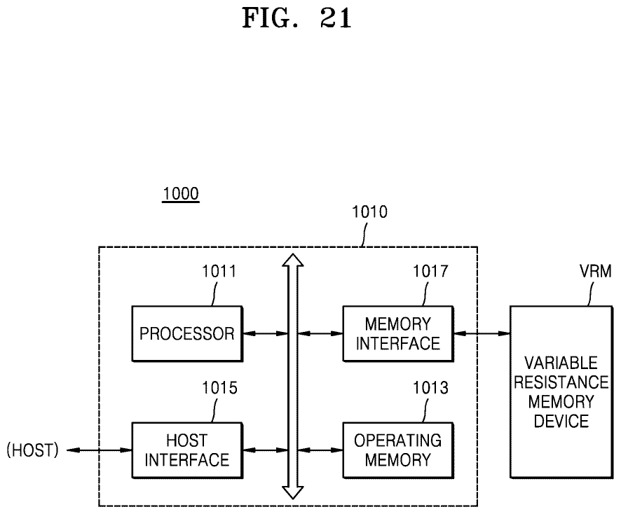

FIG. 21 is a configuration diagram of a data processing system 1000 including a variable resistance memory device according to an embodiment.

Referring to FIG. 21, the data processing system 1000 may include a memory controller 1010 connected between a host and a variable resistance memory device VRM.

The memory controller 1010 may be configured to access the variable resistance memory device VRM in response to a host's request.

The variable resistance memory device VRM may include any one of the variable resistance memory devices 100 and 200 described above. The memory controller 1010 may include a processor 1011, an operating memory 1013, a host interface 1015, and a memory interface 1017.

The processor 1011 controls the overall operation of the memory controller 1010, and the operating memory 1013 may store applications, data, and control signals necessary for the memory controller 1010 to operate. The host interface 1015 may perform protocol conversion for data/control signal exchange between the host and the memory controller 1010.

The memory interface 1017 may perform protocol conversion for data/control signal exchange between the memory controller 1010 and a variable resistance memory device VRM. Because the configuration and operating characteristics of the variable resistance memory device VRM are the same as described above, detailed description thereof is omitted.

The data processing system 1000 according to an embodiment may be a memory card, but is not limited thereto.

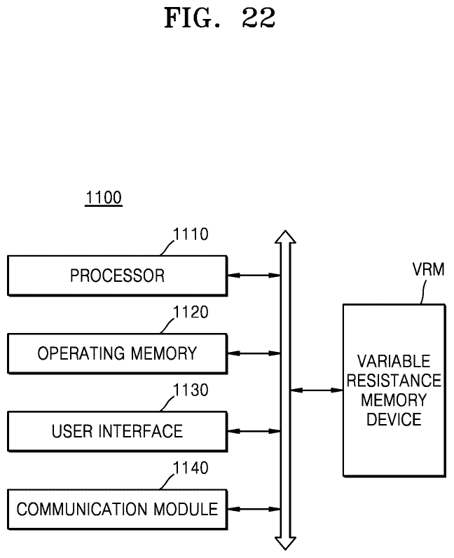

FIG. 22 is a configuration diagram of a data processing system 1100 including a variable resistance memory device according to an embodiment.

Referring to FIG. 22, the data processing system 1100 may include a variable resistance memory device VRM, a processor 1110, an operating memory 1120, and a user interface 1130, and, if necessary, may further include a communication module 1140.

The variable resistance memory device VRM may include any one of the variable resistance memory devices 100 and 200 described above.

The processor 1110 may be a central processing unit. The operating memory 1120 stores application programs, data, control signals, etc. necessary for the data processing system 1100 to operate. The user interface 1130 provides an environment in which a user may access the data processing system 1100, and provides the user with the data processing process and processing results of the data processing system 1100. Because the configuration and operating characteristics of the variable resistance memory device VRM are the same as described above, detailed description thereof is omitted.

The data processing system 1100 may be used as a disk device, as an internal/external memory card of a portable electronic device, as an image processor, or as an application chipset.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While embodiments of inventive concepts have been particularly shown and described, it will be understood that various changes in form and details may be made therein without departing from the spirit and scope of the following claims.

What is claimed is:

1. A variable resistance memory device comprising:
a cell plug;
a lower dielectric layer covering the cell plug;
a magnetic tunnel junction structure connected to the cell plug and penetrating the lower dielectric layer;
a capping pattern exposing an upper surface of the magnetic tunnel junction structure and covering both sidewalls of the magnetic tunnel junction structure;
an interlayer dielectric layer covering the lower dielectric layer and the capping pattern;
an etch stop layer exposing the upper surface of the magnetic tunnel junction structure and an upper surface of the capping pattern, the etch stop layer covering the interlayer dielectric layer;
an upper dielectric layer covering the etch stop layer; and
a contact structure penetrating the upper dielectric layer and the etch stop layer, the contact structure contacting the magnetic tunnel junction structure, wherein
the etch stop layer has a stack structure including a lower etch stop layer and an upper etch stop layer on the lower etch stop layer,
the lower etch stop layer includes metal nitride, and
the upper etch stop layer includes oxygen doped carbide.

2. The variable resistance memory device of claim 1, wherein
the metal nitride of the lower etch stop layer includes AlN, and
the oxygen doped carbide of the upper etch stop layer includes silicon oxide carbide (SiOC).

3. The variable resistance memory device of claim 2, wherein
a material in the lower etch stop layer has an etch selectivity with respect to a material in the upper etch stop layer and a material in the upper dielectric layer.

4. The variable resistance memory device of claim 3, wherein
a first portion of a sidewall of the contact structure is convexly rounded and in contact with the lower etch stop layer, and
a second portion of the sidewall of the contact structure is tapered and in contact with the upper etch stop layer.

5. The variable resistance memory device of claim 1, wherein
a vertical level of a lower surface of the lower etch stop layer is equal to a vertical level of the upper surface of the capping pattern, and
a vertical level of a lower surface of the upper etch stop layer is higher than a vertical level of the upper surface of the magnetic tunnel junction structure.

6. The variable resistance memory device of claim 5, wherein
the vertical level of the upper surface of the magnetic tunnel junction structure is higher than the vertical level of the upper surface of the capping pattern.

7. The variable resistance memory device of claim 6, wherein
the magnetic tunnel junction structure includes a lower electrode, a magnetic tunnel junction pattern, and an upper electrode,
wherein the capping pattern exposes a portion of a sidewall and an upper surface of the upper electrode and covers a sidewall of the lower electrode and a sidewall of the magnetic tunnel junction pattern.

8. The variable resistance memory device of claim 7, wherein
the upper surface of the magnetic tunnel junction structure exposed by the capping pattern corresponds to an upper surface of the upper electrode, and
the contact structure contacts a portion of a sidewall of the upper electrode and the contact structure contacts the upper surface of the upper electrode.

9. The variable resistance memory device of claim 1, wherein
the magnetic tunnel junction structure is among a plurality of magnetic tunnel junction structures spaced apart from each other, and
the capping pattern is discontinuous between neighboring magnetic tunnel junction structures among the plurality of magnetic tunnel junction structures.

10. The variable resistance memory device of claim 9, wherein
the lower dielectric layer and the interlayer dielectric layer are in contact at a portion where the capping pattern is discontinuous.

11. A variable resistance memory device comprising:
a cell plug;
a lower dielectric layer covering the cell plug;
a magnetic tunnel junction structure connected to the cell plug and penetrating the lower dielectric layer;
a capping pattern exposing an upper surface of the magnetic tunnel junction structure and covering both sidewalls of the magnetic tunnel junction structure;
an interlayer dielectric layer covering the lower dielectric layer and the capping pattern;
an etch stop layer exposing the upper surface of the magnetic tunnel junction structure and an upper surface of the capping pattern, the etch stop layer covering the interlayer dielectric layer and having a single-layer structure including metal nitride;
an upper dielectric layer covering the etch stop layer; and
a contact structure penetrating the upper dielectric layer and the etch stop layer, the contact structure contacting the magnetic tunnel junction structure.

12. The variable resistance memory device of claim 11, wherein
the single-layer structure including metal nitride of the etch stop layer includes AlN, and
a material in the etch stop layer has an etch selectivity with respect to a material in the upper dielectric layer.

13. The variable resistance memory device of claim 12, wherein,
a first portion of a sidewall of the contact structure is convexly rounded and in contact with the etch stop layer, and
a second portion of the sidewall of the contact structure is tapered and in contact with the upper dielectric layer.

14. The variable resistance memory device of claim 11, wherein
a vertical level of a lower surface of the etch stop layer is equal to a vertical level of the upper surface of the capping pattern, and
a vertical level of an upper surface of the etch stop layer is higher than a vertical level of the upper surface of the magnetic tunnel junction structure.

15. The variable resistance memory device of claim 11, wherein
the magnetic tunnel junction structure is among a plurality of magnetic tunnel junction structures spaced apart from each other, and
the capping pattern is discontinuous between neighboring magnetic tunnel junction structures among the plurality of magnetic tunnel junction structures, and
the lower dielectric layer and the interlayer dielectric layer are in contact at a portion where the capping pattern is discontinuous.

16. A variable resistance memory device comprising:
a substrate including a cell area and a peripheral circuit area surrounding the cell area;
a cell plug on the cell area;
a lower dielectric layer covering the cell plug;
a magnetic tunnel junction structure connected to the cell plug and penetrating the lower dielectric layer,
the magnetic tunnel junction structure including a lower electrode, a magnetic tunnel junction pattern, and an upper electrode;
a capping pattern covering both sidewalls of the magnetic tunnel junction structure;
an interlayer dielectric layer covering the lower dielectric layer and the capping pattern;
an etch stop layer covering the interlayer dielectric layer and including at least one layer including metal nitride;
an upper dielectric layer covering the etch stop layer; and
a contact structure penetrating the upper dielectric layer and the etch stop layer, the contact structure contacting the magnetic tunnel junction structure.

17. The variable resistance memory device of claim 16, wherein
the capping pattern exposes a portion of a sidewall of the upper electrode and an upper surface of the upper electrode,
the contact structure contacts the portion of the sidewall upper electrode and the upper surface of the upper electrode, and
the contact structure contacts an upper surface of the capping pattern.

18. The variable resistance memory device of claim 17, wherein
a first portion of a sidewall of the contact structure is convexly rounded and in contact with the etch stop layer, and
a second portion of the sidewall of the contact structure is tapered and in contact with the upper dielectric layer.

19. The variable resistance memory device of claim 16, wherein
the etch stop layer has a stack structure including a lower etch stop layer and an upper etch stop layer on the lower etch stop layer,
the lower etch stop layer includes AlN, and
the upper etch stop layer includes oxygen doped carbide.

20. The variable resistance memory device of claim 16, wherein
the etch stop layer has a single-layer structure including AlN.
